(19) United States
(12) Patent Application Publication
(10) Pub. No.: US 2023/0299720 A1
(43) Pub. Date: Sep. 21, 2023

(54) POWER AMPLIFIER BIAS CIRCUIT

(71) Applicant: NXP USA, Inc., AUSTIN, TX (US)

(72) Inventors: Elie A. Maalouf, Mesa, AZ (US); Ngai-Ming Lau, Fountain Hills, AZ (US); Xu Jason Ma, Chandler, AZ (US)

(21) Appl. No.: 17/654,946

(22) Filed: Mar. 15, 2022

(51) Int. Cl. H03F 1/02; H03F 3/24; H03F 1/32

(52) U.S. Cl. CPC H03F 1/0205; H03F 3/245; H03F 1/32; H03F 2200/451

(57) ABSTRACT

An amplifier system includes an amplifier transistor and a reference transistor used to provide a direct current (DC) bias voltage to bias a gate terminal of the amplifier transistor. The amplifier transistor may have a drain terminal coupled to a drain voltage supply and a radio frequency (RF) output node and a gate terminal coupled to bias circuitry that includes the reference transistor. The reference transistor may have a gate terminal coupled to a reference potential, a drain terminal coupled to the drain voltage supply, and a source terminal coupled to a constant current source and to the gate terminal of the amplifier transistor. The reference transistor may be formed on the same die as the amplifier transistor and may have a threshold voltage that is correlated with that of the amplifier transistor.

### TECHNICAL FIELD

Embodiments of the subject matter described herein relate generally to power amplifiers, and, more specifically, to circuitry for biasing a transistor of a power amplifier.

### BACKGROUND

Various wireless transmission systems use power amplifiers for increasing the power of a high frequency signal. In a wireless communication system, a power amplifier is usually the last amplifier in a transmission chain (i.e., the output stage). High gain, high linearity, stability, and a high level of efficiency—the ratio of radio frequency (RF) output power to direct current (DC) power—are characteristics of an ideal amplifier.

To achieve efficient operation the power amplifier, a power amplifier's power transistor is biased with direct current (DC) voltages to set the operating mode of the power transistor to achieve desired linearity and efficiency operations. However, changes in the transistor over time (e.g., material property changes in the power transistor die caused by aging, temperature, or other applicable factors) can alter the transistor's threshold voltages. As such, a bias voltage corresponding to a desired set point of the power transistor at a first time may become no longer bias the transistor as desired as the transistor's threshold voltage changes over time. As such, during operations, a transistor that performs as desired at a particular bias voltage at one time may later, begin to exhibit undesirable performance traits. For example, a failure to bias the power transistor at its threshold voltage can reduce overall power amplifier efficiency and output linearity.

### SUMMARY

A brief summary of various exemplary embodiments is presented below. Some simplifications and omissions may be made in the following summary, which is intended to highlight and introduce some aspects of the various exemplary embodiments, without limiting the scope. Detailed descriptions of an exemplary embodiment adequate to allow those of ordinary skill in the art to make and use these concepts will follow in later sections.

In an example embodiment, an amplifier device includes a first transistor and a second transistor. The first transistor may include a first gate terminal, a first source terminal, and a first drain terminal. The first transistor may be configured to amplify radio frequency (RF) signals received at the first gate terminal. The first drain terminal may be configured to be coupled to a voltage supply. The second transistor may include a second gate terminal, a second source terminal, and a second drain terminal. The second drain terminal may be configured to be coupled to the voltage supply. The second source terminal may be coupled to the first gate terminal and is configured to receive a substantially constant current from a constant current source.

In some embodiments, the amplifier device includes inverter circuitry coupled between the second source terminal of the second transistor and the first gate terminal of the first transistor. The inverter circuitry may be configured to convert a first voltage at the second source terminal of the second transistor to produce a second voltage and output the second voltage to the first gate terminal of the first transistor.

In some embodiments, the amplifier device includes a bias tee coupled to the first gate terminal of the first transistor. The bias tee may be configured to combine the second voltage and the RF signals to apply a direct current (DC) voltage offset to the RF signals.

In some embodiments, the amplifier device includes a semiconductor die on which the first transistor and the second transistor are formed.

In some embodiments, a first threshold voltage of the first transistor is correlated with a second threshold voltage of the second transistor, given variations in at least one of a temperature of the amplifier device or aging of the amplifier device.

In some embodiments, the voltage supply is configured to provide a voltage of greater than or equal to 40 V to the first drain terminal and the second drain terminal.

In some embodiments, the first transistor and the second transistor are each gallium nitride field effect transistors.

In an example embodiment, an amplifier system includes an amplifier transistor having a first gate terminal, a first source terminal, and a first drain terminal, bias circuitry that includes a reference transistor having a second gate terminal, a second source terminal, and a second drain terminal and inverter circuitry coupled between the second source terminal of the reference transistor and the first gate terminal of the amplifier transistor, a constant current source configured to supply a substantially constant current to the second source terminal of the reference transistor, and a voltage supply coupled to the first drain terminal of the amplifier transistor and coupled to the second drain terminal of the reference transistor.

In some embodiments, the amplifier transistor and the reference transistor are formed on the same substrate.

In some embodiments, the amplifier system includes a bias tee coupled between the bias circuitry and the first gate terminal of the amplifier transistor, and a RF signal source coupled to the first gate terminal of the amplifier transistor via the bias tee. The RF signal source may be configured to supply RF signals to the first gate terminal of the amplifier transistor. The bias circuitry may be configured to provide a DC bias voltage to the first gate terminal of the amplifier transistor.

In some embodiments, the inverter circuitry is configured to generate the DC bias voltage by inverting a source voltage at the second source terminal of the reference transistor.

In some embodiments, a first threshold voltage of the amplifier transistor is correlated with a second threshold voltage of the reference transistor, given variations in at least one of a temperature or aging.

In some embodiments, the voltage supply is configured to output a voltage of greater than or equal to 40 V to the first drain terminal of the amplifier transistor and the second drain terminal of the reference transistor.

In an example embodiment, an amplifier system includes a carrier amplifier and a peaking amplifier. The carrier amplifier includes a first amplifier transistor having a first gate terminal, a first source terminal, and a first drain terminal, and a first reference transistor having a second gate terminal, a second source terminal, and a second drain terminal. The first amplifier transistor may be configured to amplify radio frequency (RF) signals received at the first gate terminal. The first drain terminal may be configured to be coupled to a first voltage supply. The second drain terminal may be configured to be coupled to the first voltage supply. The second source terminal may be coupled to the first gate terminal and may be configured to receive a first constant current from a first constant current source. The peaking amplifier may include a second amplifier transistor having a third gate terminal, a third source terminal, and a third drain terminal and a second reference transistor having a fourth gate terminal, a fourth source terminal, and a fourth drain terminal. The second amplifier transistor may be configured to amplify radio frequency (RF) signals received at the third gate terminal. The third drain terminal may be configured to be coupled to a second voltage supply. The fourth drain terminal may be configured to be coupled to the second voltage supply. The fourth source terminal may be coupled to the third gate terminal and may be configured to receive a second constant current from a second constant current source.

In some embodiments, the amplifier system includes first inverter circuitry coupled between the second source terminal of the first reference transistor and the first gate terminal of the first amplifier transistor and second inverter circuitry coupled between the fourth source terminal of the second reference transistor and the third gate terminal of the second amplifier transistor.

In some embodiments, the first inverter circuitry is configured to invert a first source voltage at the second source terminal of the first reference transistor to provide a first direct current (DC) bias voltage at the first gate terminal of the first amplifier transistor, and the second inverter circuitry is configured to invert a second source voltage at the fourth source terminal of the second reference transistor to provide a second DC bias voltage at the third gate terminal of the second amplifier transistor.

In some embodiments, the first amplifier transistor and the first reference transistor are formed on a first semiconductor die, and the second amplifier transistor and the second reference transistor are formed on a second semiconductor die.

In some embodiments, a first threshold voltage of the first amplifier transistor is correlated with a second threshold voltage of the first reference transistor, and a third threshold voltage of the second amplifier transistor is correlated with a fourth threshold voltage of the second reference transistor.

In some embodiments, the first voltage supply is configured to supply a first voltage of greater than or equal to 40 V to the first drain terminal of the first amplifier transistor and to the second drain terminal of the first reference transistor, and the second voltage supply is configured to supply a second voltage of greater than or equal to 40 V to the third drain terminal of the second amplifier transistor and to the fourth drain terminal of the second reference transistor.

In some embodiments, the first amplifier transistor, the second amplifier transistor, the first reference transistor, and the second reference transistor are gallium nitride field effect transistors.

### BRIEF DESCRIPTION OF THE DRAWINGS

A complete understanding of the subject matter may be derived by referring to the detailed description and claims when considered in conjunction with the following figures, wherein like reference numbers refer to similar elements throughout the figures.

FIG. 1 is a block diagram of an example amplifier device that includes an amplifier transistor and bias circuitry coupled to a gate of the amplifier transistor, according to an embodiment.

FIG. 2 is a block diagram of an example amplifier system that includes an amplifier transistor and bias circuitry coupled to a gate of the amplifier transistor, where the bias circuitry includes a reference transistor that is coupled between a voltage supply and a constant current source to dynamically set a bias voltage for the amplifier transistor, according to an embodiment.

FIG. 3 is a block diagram of an example Doherty amplifier system that includes first bias circuitry including a first reference transistor that is coupled to a carrier amplifier transistor and second bias circuitry including a second reference transistor that is coupled to a peaking amplifier transistor, according to an embodiment.

FIG. 4 is a graph illustrating the respective current passing through the reference transistor and amplifier transistor at different gate voltages, according to an embodiment.

### DETAILED DESCRIPTION

The following detailed description is merely illustrative in nature and is not intended to limit the embodiments of the subject matter or the application and uses of such embodiments. As used herein, the words “exemplary” and “example” mean “serving as an example, instance, or illustration.” Any implementation described herein as exemplary or an example is not necessarily to be construed as preferred or advantageous over other implementations. Furthermore, there is no intention to be bound by any expressed or implied theory presented in the preceding technical field, background, or the following detailed description.

For the sake of brevity, conventional semiconductor fabrication techniques may not be described in detail herein. In addition, certain terms may also be used herein for reference only, and thus are not intended to be limiting. For instance, the terms “first”, “second”, and other such numerical terms referring to structures do not imply a sequence or order unless clearly indicated by the context.

Power amplifiers, such as those incorporated into wireless transmission systems, include one or more amplifier transistors configured to amplify the power of a high frequency signal to a level suitable for transmission. To provide desired operation of the power amplifier (e.g., to achieve desired power efficiency and/or a desired degree of output linearity), direct current (DC) bias voltages are applied at the gate terminal of an amplifier transistor of the power amplifier to bias the amplifier transistor for operation along a desired portion of its operating curve. However, variations in an amplifier transistor's performance over time (e.g., due to manufacturing variations, temperature variations, aging processes, or other applicable factors affecting the transistor die) can produce changes in the transistor's threshold voltages (e.g., the transistor's gate-to-source threshold voltage) over time. As such, bias voltages that may appropriately bias a transistor at one time may not properly bias the same transistor at another time. A failure to bias a power amplifier properly based upon the transistor's threshold voltages of its constituent transistors can reduce overall power amplifier efficiency and linearity.

The present disclosure, therefore, provides bias circuitry that may be utilized to dynamically provide suitable biasing voltages for one or more amplifier transistors of a power amplifier. As such, embodiments of the present bias circuitry may serve to mitigate poor amplifier performance due to part-to-part and temporal transistor bias variations that can occur due to the aforementioned variation of transistor threshold voltages due to process variations, age, temperature changes, or other applicable factors. By allowing for the dynamic determination of suitable bias control voltages for an amplifier transistor, the present bias circuitry can reduce the need for extensive and manual bias calibration routines that may typically be implemented by end users to account for variations in relation to conventional power amplifier modules.

In some embodiments, bias circuitry described herein may be utilized in conjunction with a power amplifier that includes an amplifier transistor and a reference transistor integrated into the same die. Because the reference transistor and the amplifier transistor are incorporated into the same die and may be of the same type (e.g., each transistor may an n-type deletion mode gallium nitride (GaN) field effect transistors (FET)), the reference transistor and the amplifier transistor may exhibit similar or correlated variations in performance due to process variations, aging, temperature variations, and/or other applicable factors. Drain terminals of the amplifier transistor and the reference transistor may each be coupled to the same drain voltage supply. A gate terminal of the reference transistor may be coupled to a reference potential (e.g., ground). A source terminal of the reference transistor may be connected to a constant current source and may be coupled to a gate terminal of the amplifier transistor via inverter circuitry (e.g., an operational amplifier inverter). In this way, when a positive voltage is applied at the source terminal of the reference transistor, a corresponding negative voltage is applied to bias the gate terminal of the amplifier transistor to achieve a desired operation of the amplifier transistor.

By supplying the same drain voltage to the drain terminals of the reference transistor and the amplifier transistor, the need to provide a separate drain voltage supply for the reference transistor (via, a charge pump, for example) may be avoided, enabling reductions in the die size and cost of the amplifier transistor. Various embodiments of bias circuitry described herein utilize a constant current source to set the voltage at the source terminal of the reference transistor and, in conjunction with the inverter circuitry, to set the DC bias voltage used to bias the gate terminal of the amplifier transistor. Such bias circuitry corresponds to an open loop system. At least because the bias circuitry is an open loop system in such embodiments, RF noise at the reference transistor may be mitigated using decoupling circuitry, such as one or more RF decoupling capacitors coupled between the source or drain of the reference transistor and the reference potential (e.g., ground). For example, such RF decoupling capacitors, when used in a closed loop system for controlling the gate voltage at the amplifier transistor, undesirably reduce the phase margin of the system, potentially destabilizing the closed loop system and/or causing unintended loop oscillation. However, because embodiments of the bias circuitry described herein correspond to open loop systems, such RF decoupling capacitors may be used to mitigate RF noise from the amplifier transistor that may interfere with the reference transistor.

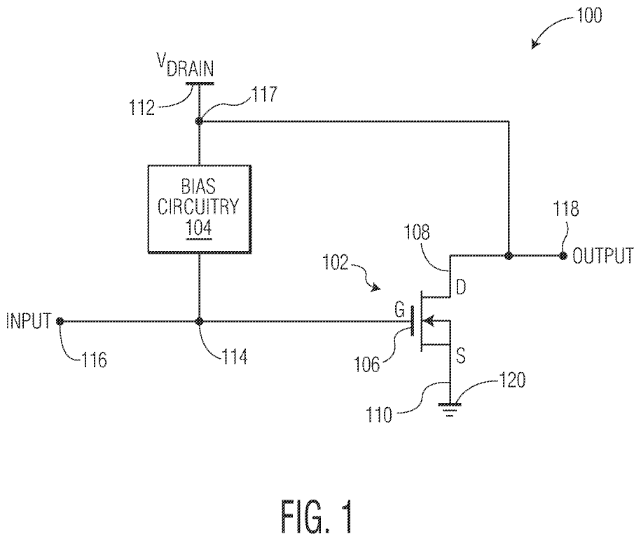

FIG. 1 depicts a block diagram of an exemplary amplifier device 100. The amplifier device 100 includes an amplifier transistor 102 having a gate (G) terminal 106, a drain (D) terminal 108, and a source (S) terminal 110.

The amplifier transistor 102 may be a field-effect transistor (FET), such as a gallium nitride (GaN) FET, suitable for use, for example, in a radio frequency (RF) power amplifier circuit capable of operating at frequencies above about 400 megahertz (MHz), although other applicable transistor devices can be used, with or without modifications to the amplifier device 100, as will be understood by those of ordinary skill. The amplifier transistor 102 may be a power amplifier transistor, for example. Such power amplifier circuits may be employed, for instance, in a multi-carrier and/or single-carrier wireless base station. In some embodiments, the amplifier transistor 102 is an “n-channel” or “n-type” depletion mode GaN FET having a negative threshold voltage. Herein, a “threshold voltage” refers to a threshold gate-to-source voltage required to change the state of a transistor (e.g., from an “on” state to an “off” state, or vice versa). For example, for a given n-channel depletion mode transistor, a conductive channel exists between the source and the drain when little or no gate voltage is applied, and by applying a negative voltage to the gate that exceeds the threshold voltage for the transistor, the mobile charge carriers in the channel are depleted, causing the transistor to transition from an “on” state to an “off” state.

In some alternate embodiments, the amplifier transistor 102 may be another type of III-V transistor (e.g., gallium arsenide (GaAs), gallium phosphide (GaP), indium phosphide (InP), or indium antimonide (InSb)), or another type of transistor that has a relatively low drain-source capacitance. In various embodiments, the substrate of amplifier device 100 in which amplifier transistor 102 is formed generally includes bulk or composite semiconductor materials (e.g., silicon (Si), gallium nitride (GaN), gallium arsenide (GaAs), silicon-on-insulator (SoI), silicon germanium (SiGe), GaN-on-insulator (e.g., GaN on Si, GaN on silicon carbide, GaN on sapphire, and so on), or other suitable materials).

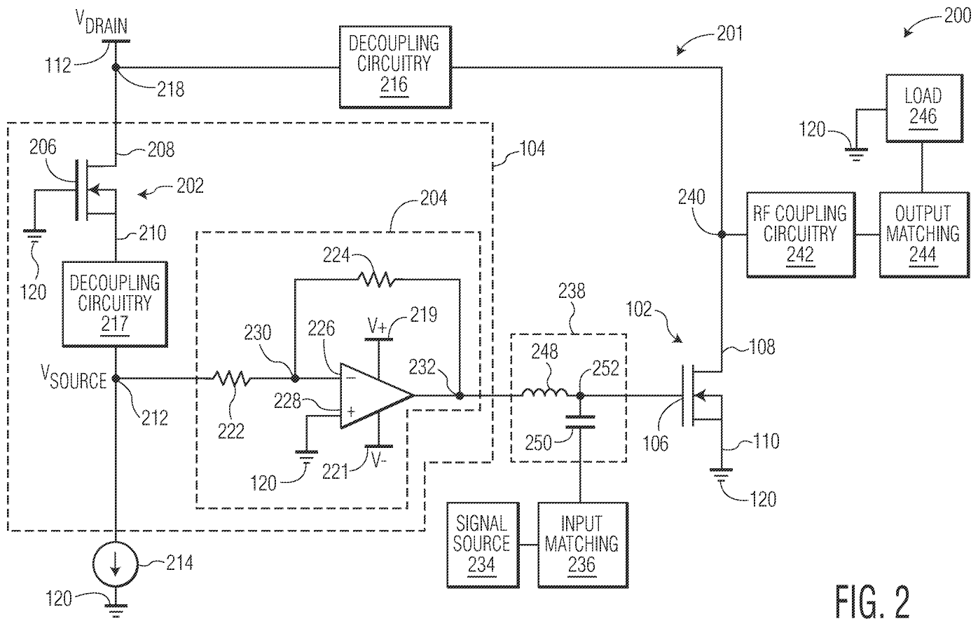

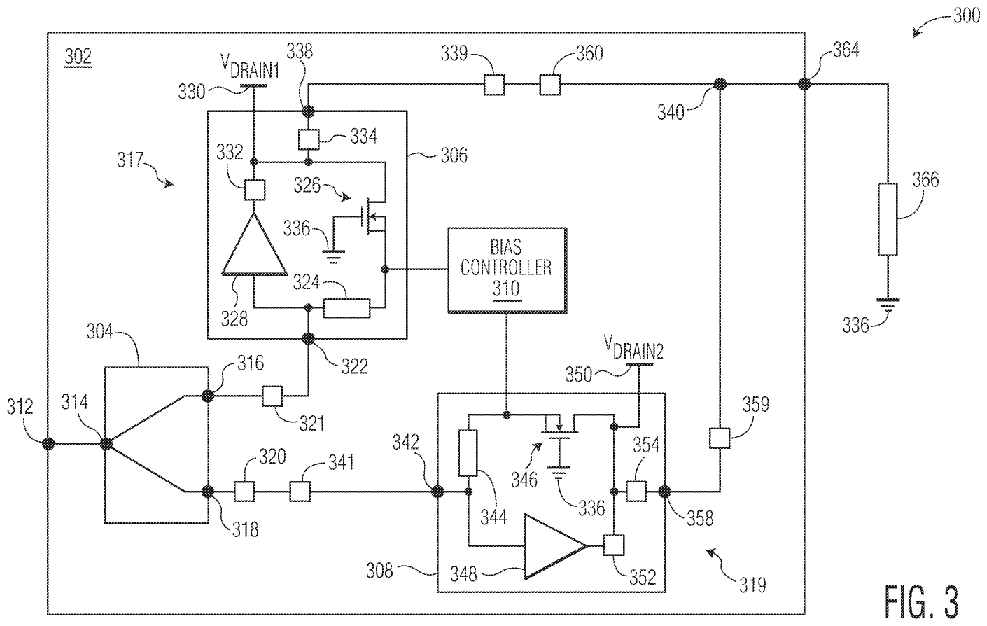

An input node 116 of the amplifier device 100 is coupled to the gate terminal 106 of the amplifier transistor 102. An output node 118 of device 100 is coupled to the drain terminal 108 of the amplifier transistor 102. The source terminal 110 of the amplifier transistor 102 may be connected to a reference potential 120, such as a ground reference plane or direct current (DC) reference voltage supply, which may provide a ground voltage or a non-ground reference voltage, for example. In some embodiments, RF signals received at the input node 116 are amplified by the amplifier transistor 102 to produce an amplified RF signal at the output node 118. In some embodiments, coupling circuitry (e.g., a DC blocking capacitor) is coupled between the output node 118 and a load (not shown; an embodiment of the load 246, 366, FIGS. 2, 3, for example) to which the amplifier device 100 is connected in order to remove DC voltage bias from the amplified signal.

The amplifier device 100 includes bias circuitry 104 coupled between a drain voltage node 117 and a combining node 114. The bias circuitry 104 may include an input for receiving a drain voltage (V_{DRAIN}) from a drain voltage supply 112 via a drain voltage node 117. I In some embodiments, the drain voltage V_{DRAIN} is greater than 40 V (e.g., around 48 V). The drain voltage supply 112 may also supply the drain voltage V_{DRAIN} to the drain terminal 108 of the amplifier transistor 102 via the drain voltage node 117. For example, by providing the drain voltage V_{DRAIN} to the bias circuitry 104, instead of using a separate voltage supply and charge pump to supply voltage to the bias circuitry 104, the die size of an integrated circuit die that includes the amplifier device 100 may be reduced and costs associated with implementing a separate voltage supply and charge pump may be reduced.

In some embodiments, decoupling circuitry (e.g., an embodiment of the decoupling circuitry 216, 332, 352, FIGS. 2, 3, for example) is coupled along the path between the drain voltage node 117 and the drain terminal 108 of the amplifier transistor 102. For example, the decoupling circuitry may include a capacitor (e.g., a shunt capacitor; sometimes referred to herein as an “RF decoupling capacitor”) coupled between the path and the reference potential 120 to redirect RF signals to the reference potential 120 that would otherwise interfere with performance of the bias circuitry 104. The decoupling circuitry may additionally or alternatively include an inductor coupled in series along the path to block RF signals from passing from the drain voltage node 117 to the bias circuitry 104. In some embodiments, such decoupling circuitry may additionally or alternatively be disposed along the path between the node 114 and the bias circuitry 104 to block and/or redirect RF signals from the input node 116. The decoupling circuitry may mitigate RF noise that would otherwise be received at the bias circuitry 104 from the input node 116, the drain terminal 108 of the amplifier transistor 102, or both (e.g., by providing one or more low impedance paths to ground for higher frequency signals via the shunt capacitor(s) and/or blocking higher frequency signals via the series inductor(s)). According to various embodiments, the drain voltage supply 112 may be included in the amplifier device 100, or, alternatively, may be an external voltage supply that is coupled to the amplifier device 100.

The bias circuitry 104 is configured to supply a DC bias voltage to the gate terminal 106 of the amplifier transistor 102, where the DC bias voltage biases the amplifier transistor 102 into a desired mode of operation. During operation of the amplifier device 100, the quiescent bias current of a transistor device remains substantially constant over temperature variations, device aging, process variations, and/or other applicable factors so that degradation in performance (e.g., linearity, gain, efficiency, etc.) over time is mitigated in an amplifier circuit utilizing the amplifier device 100. Because the quiescent bias current of the amplifier transistor 102 is largely dependent upon, among other parameters, a threshold voltage of the device, which can exhibit a temperature and age dependence, biasing the amplifier transistor 102 with a fixed bias voltage may result in inconsistent performance of the amplifier transistor 102. Thus, in various embodiments, the DC bias voltage supplied by bias circuitry 104 is dynamically selected to bias the amplifier transistor 102 at a substantially constant quiescent operating point (e.g., such that quiescent current through the amplifier transistor 102 is substantially constant). For example, the bias circuitry 104 may dynamically change the DC bias voltage supplied to gate terminal 106 of the amplifier transistor 102 via the combining node 114, responsive to changes in temperature or changes in electrical characteristics (e.g., threshold voltage drift due to aging) of the amplifier transistor 102. In one or more embodiments, the bias circuitry 104 includes a reference transistor (such as the reference transistor 202, 326, 346, FIGS. 2, 3, as nonlimiting examples) having a gate terminal coupled to ground, a drain terminal coupled to the drain voltage supply 112, and a source terminal coupled to a constant current source that is configured to supply a constant current corresponding to the desired quiescent current for the amplifier transistor 102, resulting in a source voltage at the source terminal of the reference transistor. The reference transistor may be operated in a self-biased mode, in which the gate terminal of the reference transistor is coupled to a reference potential (e.g., ground voltage). The source terminal of the reference transistor may be coupled to the combining node 114 via inverter circuitry that inverts the source voltage at the source terminal and supplies the inverted source voltage to bias the gate terminal 106 of the amplifier transistor 102 as the DC bias voltage.

As shown, the combining node 114 is coupled to and interposed between the input node 116 and the gate terminal 106 of the amplifier transistor 102. In some embodiments, a bias tee (not shown; an embodiment of the bias tee 238 of FIG. 2, for example) is disposed at the combining node 114. The bias tee may include a capacitor coupled between the input node 116 and the combining node 114 and an inductor coupled between the bias circuitry 104 and the combining node 114. The inductor of the bias tee blocks higher frequency signals (e.g., RF noise) from the bias circuitry 104 while allowing lower frequency (e.g., DC) signals from the bias circuitry 104 to pass to the gate terminal 106. The capacitor of the bias tee blocks lower frequency signals from the input node 116 and allows higher frequency signals (e.g., RF signals) to pass to the gate terminal 106. In this way, the bias tee at the combining node 114 may combine RF signals provided via the input node 116 with the DC bias voltage provided by the bias circuitry 104.

FIG. 2 shows an illustrative diagram of an amplifier system 200, which may include an amplifier device 201, a signal source 234 configured to produce RF signals, and a load 246 configured to receive amplified RF signals. In some embodiments, the amplifier device 201 corresponds to an example embodiment of the amplifier device 100 of FIG. 1. In FIG. 2, like reference numerals are used to denote similar elements in FIG. 1, and some details already discussed above in conjunction with such elements are not reiterated here for brevity.

In the present example, the amplifier device 201 includes the amplifier transistor 102. The source terminal 110 of the amplifier transistor 102 is coupled (e.g., directly coupled) to the reference potential 120. The drain terminal 108 of the amplifier transistor 102 is coupled to the drain voltage supply 112, which supplies the drain voltage V_{DRAIN}. The gate terminal 106 of the amplifier transistor 102 is coupled to the bias circuitry 104 (via a bias tee 238, described in more detail below).

In some embodiments, the drain terminal 108 of the amplifier transistor 102 is coupled to the drain voltage supply 112 via a drain voltage node 218. In various embodiments, one or both of decoupling circuitry 216 and decoupling circuitry 217 may be coupled to the drain terminal 208 or the source terminal 210, respectively, of the reference transistor 202. For example, the decoupling circuitry 216 may be disposed along a path between the drain voltage node 218 and the drain terminal 108 of the amplifier transistor 102. For example, the decoupling circuitry 216 and the decoupling circuitry 217 may each respectively include a series inductor, a shunt capacitor, or both. The decoupling circuitry 216 may be configured to block higher frequency (e.g., RF) signals from passing from the drain terminal 108 of the amplifier transistor 102 to the drain terminal 208 of the reference transistor 202, while allowing lower frequency (e.g., DC) signals to pass. In this way, the decoupling circuitry 216 may mitigate RF noise that would otherwise be received at the drain terminal 208 of the reference transistor 202 from the the drain terminal 108 of the amplifier transistor 102. The decoupling circuitry 217 may be configured to block higher frequency (e.g., RF) signals from passing from signal source 234 to the source terminal 210 of the reference transistor 202, while allowing lower frequency (e.g., DC) signals to pass. In this way, the decoupling circuitry 217 may mitigate RF noise that would otherwise be received at the source terminal 210 of the reference transistor 202 from the signal source 234.

The bias circuitry 104 includes a reference transistor 202 and inverter circuitry 204. The reference transistor 202 includes a gate terminal 206, a drain terminal 208, and a source terminal 210. The gate terminal 206 of the reference transistor 202 is coupled (e.g., directly coupled) to the reference potential 120. The drain terminal 208 of the reference transistor 202 is coupled to the drain voltage supply 112. The source terminal 210 of the reference transistor 202 is connected to a source voltage node 212. The source voltage node 212 is connected to a constant current source 214. The constant current source 214 may be a high accuracy current source (e.g., a current source that supplies current within +/−3% of a target current value). In some embodiments, the constant current source 214 is included in a bias controller (e.g., an embodiment of the bias controller 310 of FIG. 3) that is coupled to or included in the amplifier device 201. The constant current source 214 is configured to provide a variable source voltage, V_{SOURCE}, at the source voltage node 212 in order to pull a substantially constant current (e.g., around 10 mA) through the reference transistor 202. In some embodiments, the value of the constant current supplied by the constant current source 214 may be dynamically set (e.g., by a bias controller that includes the constant current source 214) based on a detected temperature (e.g., determined by one or more temperature sensors coupled to the bias controller) of the amplifier device 201.

The inverter circuitry 204 may be an operational amplifier inverter, as shown in the present example. The inverter circuitry 204 may include a first resistor 222, a second resistor 224, and an operational amplifier 220. The first resistor 222 (e.g., having a resistance of around 10 kΩ) may be coupled between the source voltage node 212 and a node 230. The second transistor may be coupled between the node 230 and a node 232. The node 232 may be coupled to the gate terminal 106 of the amplifier transistor 102 (e.g., via the bias tee 238). The operational amplifier 220 may include an inverting input 226 coupled to the node 230 and a non-inverting input 228 coupled to the reference potential 120. For example, the inverter circuitry 204 receives the source voltage V_{SOURCE} at the source voltage node 212, inverts the source voltage V_{SOURCE}, and provides the resultant inverted voltage at the node 232 as the DC bias voltage used to bias the gate of the amplifier transistor 102. The operational amplifier 220 may be coupled between a positive voltage rail 219 and a negative voltage rail 221. For example, the positive voltage rail 219 may supply a positive voltage V₊ of around 5 V and the negative voltage rail 221 may supply a negative voltage V₋ of around −8 V.

The reference transistor 202 may be formed on the same substrate (corresponding to a semiconductor die, for example) as the amplifier transistor 102. In some embodiments, the substrate comprises silicon carbide (SiC) on which type-III nitride material (e.g., GaN) is formed (e.g., epitaxially grown) to form active devices, such as the reference transistor 202 and the amplifier transistor 102. In some embodiments, the reference transistor 202 and the amplifier transistor 102 are the same type of transistor (e.g., both are n-type GaN FETs). In the present example, the reference transistor 202 and the amplifier transistor 102 are each depletion mode transistor, each having a respective negative threshold voltage. The reference transistor 202 may be smaller than the amplifier transistor 102. For example, in one or more embodiments, the reference transistor 202 may have a gate width of around 40 μm to around 60 μm (e.g., 50 μm) and the amplifier transistor 102 may have a gate width in a range of around 1 mm to around 10 mm (e.g., 2 mm or 5 mm). In an example embodiment in which the amplifier system 200 is a carrier amplifier of a Doherty amplifier system, the gate width of the amplifier transistor 102 may be around 2 mm. In an example embodiment in which the amplifier system 200 is a peaking amplifier of a Doherty amplifier system, the gate width of the amplifier transistor 102 may be around 5 mm.

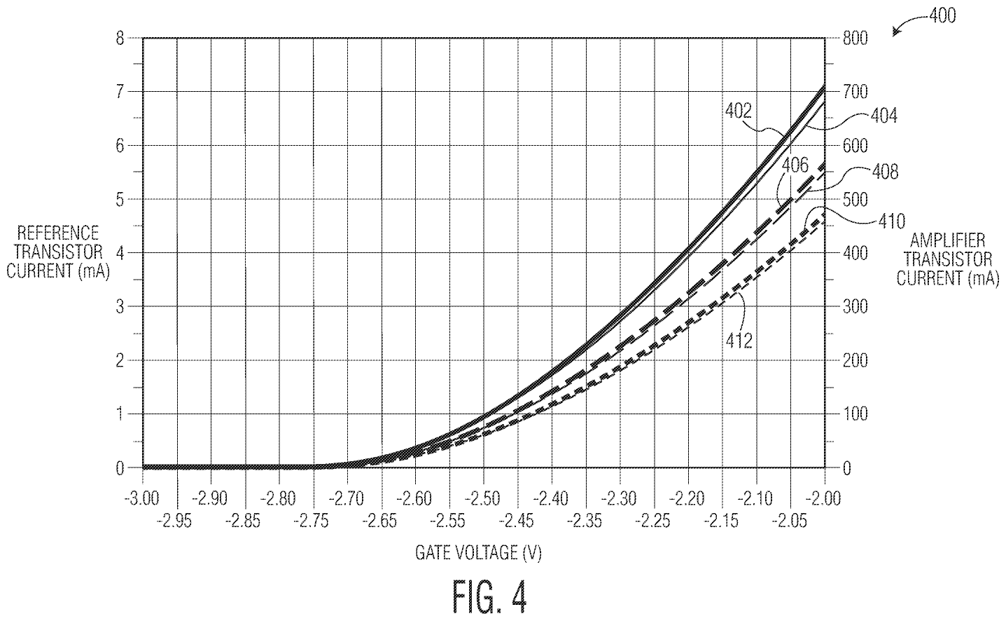

In one or more embodiments, at least one characteristic (e.g., threshold voltage) of the reference transistor 202 correlates with one or more corresponding characteristics of the amplifier transistor 102 across variations in temperature, age, or other applicable factors (as shown in the FIG. 4, for example). For example, as the threshold voltage of the reference transistor 202 decreases due to factors such as increasing temperature or age, the threshold voltage of the amplifier transistor 102 decreases by a correlated amount. Because the gate terminal 206 of the reference transistor 202 is coupled to the reference potential 120 (e.g., ground) and the source terminal 210 of the reference transistor 202 is coupled to the source voltage node 212, the source voltage V_{SOURCE} needed to achieve the constant current flow set by the constant current source 214 changes as the threshold voltage of the reference transistor 202 changes (and, therefore, as the threshold voltage of the amplifier transistor 102 changes). Because the source voltage V_{SOURCE} is inverted by the inverter circuitry 204 to produce the DC bias voltage for biasing the gate terminal 106 of the amplifier transistor 102, this dynamically biases the gate terminal 106 of the amplifier transistor 102 to accommodate for changes in the threshold voltage of the amplifier transistor 102 due to, for example, temperature, aging, or other applicable factors.

As shown, both the reference transistor 202 and the amplifier transistor 102 operate from the same drain voltage supply 112. By providing the same drain voltage V_{DRAIN} to both the drain terminal 108 of the amplifier transistor 102 and the drain terminal 208 of the reference transistor 202 of the bias circuitry 104, instead of using a separate voltage supply and charge pump to supply voltage to drain terminal 208, the die size of an integrated circuit die that includes the amplifier device 201 may be reduced and costs associated with implementing a separate voltage supply and charge pump may be reduced.

In the present example, the bias circuitry 104 may be an open loop system that regulates the gate voltage at the gate of the amplifier transistor 102. At least because the bias circuitry 104 is an open loop system, decoupling circuitry, such as the decoupling circuitry 216, the decoupling circuitry 217, or both may be used to mitigate RF signal interference at the reference transistor 202 without destabilizing the bias circuitry 104 (which would be a concern if the bias circuitry 104 were a closed loop system, due to potential reduction in phase margin and risk of unintended loop oscillation by introducing such decoupling circuitry in closed loop systems).

In some embodiments, the signal source 234 is coupled to the amplifier device 201 via input impedance matching network 236 and the bias tee 238. The signal source 234 may be an RF signal source configured to supply RF signals to the gate terminal 106 of the amplifier transistor 102 (e.g., for power amplification of the RF signals by the amplifier transistor 102). The input impedance matching network 236 may be configured to reduce the impedance mismatch between an input impedance of the amplifier device 201 and an impedance of the signal source 234. For example, the input impedance matching network 236 may be coupled between the signal source 234 and the bias tee 238. In the present example, the bias tee 238 includes an inductor 248 coupled between the node 232 and a combining node 252 and includes a capacitor 250 coupled between the input impedance matching network 236 and the combining node 252. The inductor 248 may act as a low pass filter that blocks higher frequency (e.g., RF) signals and passes lower frequency (e.g., DC) signals. The capacitor 250 may act as a high pass filter that passes higher frequency (e.g., RF) signals and blocks lower frequency (e.g., DC) signals. Thus, the DC bias voltage provided at the node 232 (i.e., the voltage produced by inverting the source voltage V_{SOURCE}) passes through the inductor 248 to the combining node 252 and the RF signal output by the signal source 234 passes through the input impedance matching network 236 and the capacitor 250 to the combining node 252, where DC bias voltage and the RF signal are combined at the combining node 252. In this way, the bias tee 238 combines the inverted DC voltage (inverted V_{SOURCE}) output at the node 232 with RF signals output by the signal source 234, thereby applying a DC offset to the RF signals.

The amplifier device 201 is coupled to a load 246 via RF coupling circuitry 242 and output impedance matching network 244, in the present example. The RF coupling circuitry 242 may be coupled between the output node 240 and the output impedance matching network 244. The output impedance matching network 244 may be coupled between the RF coupling circuitry 242 and the load 246. The load 246 may be coupled between the output impedance matching network 244 and the reference potential 120. The output impedance matching network 244 may be configured reduce an impedance mismatch between an output impedance of the amplifier device 201 and an impedance of the load 246. The RF coupling circuitry 242 may, for example, include a DC blocking capacitor that acts as a high-pass filter, allowing amplified RF signals at the output node 240 to pass to the load 246 while blocking low frequency (e.g., DC) portions of the signals at the output node 240.

FIG. 3 shows a diagram of an example Doherty amplifier system 300 (sometimes referred to as a Doherty power amplifier system), according to one or more embodiments. The amplifier system 300 includes a carrier amplifier 306 and a peaking amplifier module 308 that each include bias circuitry corresponding to, for example, respective embodiments of the bias circuitry 104 of FIGS. 1 and 2. As shown in FIG. 3, some or all components of the Doherty amplifier system 300 may be implemented in a single device package or module 302.

The Doherty amplifier system 300 includes the carrier amplifier 306 (sometimes referred to as a carrier amplifier die 306), the peaking amplifier 308 (sometimes referred to as a peaking amplifier die 308), and a bias controller 310. The carrier amplifier 306 may be a Class AB or Class B amplifier, while the peaking amplifier may be a class C amplifier, for example. The bias controller 310 is electrically coupled to both the carrier amplifier 306 and the peaking amplifier 308. While shown to be single stage amplifier devices in the present example, the carrier amplifier 306 and the peaking amplifier 308 may instead be dual stage amplifier devices or may have more than two amplification stages in some alternative embodiments.

Additionally, the Doherty amplifier system 300 may include an RF input node 312, an RF output node 364, a power divider 304, a combining node 340, a first phase delay element 320, a second phase delay element 360, a first input impedance matching network 321, a second input impedance matching network 341, a first output impedance matching network 339, and a second output impedance matching network 359. The RF output node 364 may be coupled to a load 366, such as an antenna. The load 366 may be coupled between the RF output node 364 and a reference potential 336 (e.g., a ground voltage). As shown, the RF input node 312 may be coupled to a power divider input node 314 of the power divider 304. The RF input node 312 may be coupled to a signal source (not shown; an embodiment of the signal source 234 of FIG. 2, for example) configured to generate RF signals and provide the RF signals to the RF input node 312. The power divider 304 is configured to divide the power of an input RF signal received at the power divider input node 314 from the RF input node 312 into carrier and peaking portions (herein, a “carrier input signal” and a “peaking input signal”). The carrier input signal is provided from a first power divider output node 316 to a carrier amplification path 317 that is coupled between the first power divider output node 316 and the combining node 340 and that includes the carrier amplifier 306. The peaking input signal is provided from a second power divider output node 318 to a peaking amplification path 319 that is coupled between the second power divider output node 318 and the combining node 340 and that includes the peaking amplifier 308.

In some embodiments, the Doherty amplifier system 300 is configured to operate using a symmetric Doherty amplifier configuration in which the power divider 304 is configured to divide a received RF input signal such that approximately one half of the input signal power is apportioned to the carrier input signal output at the first power divider output node 316 and approximately one half of the input signal power is apportioned to the peaking input signal output at the second power divider output node 318. In other embodiments, the Doherty amplifier system 300 is configured to operate using an asymmetric Doherty amplifier configuration in which the power divider 304 is configured to divide a received RF input signal apportions input signal power unequally between the carrier input signal and the peaking input signal when dividing an RF input signal.

The carrier input signal that is output at the first power divider output node 316 is received at a carrier amplifier input node 322 of the carrier amplifier 306. The first input impedance matching network 321 may be coupled between the first power divider output node 316 and the carrier amplifier input node 322. The first input impedance matching network 321 may include a network of inductors, capacitors, and/or resistors configured to reduce an impedance mismatch between an input impedance of the carrier amplifier 306 and a source impedance (e.g., the impedance of a signal source coupled to the RF input node 312).

The carrier amplifier 306 may include, in addition to the carrier amplifier input node 322, a carrier amplifier transistor 328 (e.g., an embodiment of the amplifier transistor 102 of FIGS. 1, 2), a first reference transistor 326 (e.g., an example embodiment of the reference transistor 202 of FIG. 2), first inverter circuitry 324 (e.g., an example embodiment of the inverter circuitry 204 of FIG. 2), first decoupling circuitry 332 (e.g., an example embodiment of the decoupling circuitry 216 of FIG. 2), first RF coupling circuitry 334 (e.g., an example embodiment of the RF coupling circuitry 242 of FIG. 2), and a carrier amplifier output node 338.

Drain terminals of the carrier amplifier transistor 328 and the first reference transistor 326 may be coupled to a first drain voltage supply 330 (configured to supply a first drain voltage V_{DRAIN1} of, for example, around 48 V). The first decoupling circuitry 332 may be coupled between the carrier amplifier transistor 328 (e.g., a drain terminal thereof) and the reference transistor 326. In other embodiments, similar decoupling circuitry (e.g., decoupling circuitry 217 of FIG. 2) may be coupled to a source terminal of the reference transistor 326. The first decoupling circuitry 332 may reduce RF signal interference at the reference transistor 326.

The drain terminals of the carrier amplifier transistor 328 and the first reference transistor 326 may also be coupled to the carrier amplifier output node 338 via the first RF coupling circuitry 334. The gate terminal of the first reference transistor 326 and the source terminal of the carrier amplifier transistor 328 may each be coupled to a reference potential 336 (e.g., a ground voltage). The gate terminal of the carrier amplifier transistor 328 may be coupled to the carrier amplifier input node 322 and may be coupled to the source terminal of the first reference transistor 326 via the first inverter circuitry 324. The carrier amplifier transistor 328 and the first reference transistor 326 may be formed on the same substrate (semiconductor die). A threshold voltage of the first reference transistor 326 may be correlated with a threshold voltage of the carrier amplifier transistor 328, given changes in temperature and aging, for example, of the carrier amplifier 306. In this way, the DC bias voltage supplied at the gate terminal of the carrier amplifier transistor 328 (which is based on the source voltage at the source terminal of the first reference transistor 326) is dynamically adjusted to account for changes in the threshold voltage of the carrier amplifier transistor 328 due to temperature, aging, or other applicable factors.

The bias controller 310 may include a constant current source (e.g., an example embodiment of the constant current source 214 of FIG. 2) configured to supply a constant current (e.g., around 10 mA) at the source terminal of the first reference transistor 326. In some embodiments, the bias controller 310 includes the first drain voltage supply 330 that supplies the first drain voltage V_{DRAIN1}. In some embodiments, the first drain voltage V_{DRAIN1} is greater than 40 V (e.g., around 48 V). During operation of the Doherty amplifier system 300, a source voltage at a source terminal of the first reference transistor 326 is inverted by the first inverter circuitry 324 to produce a DC bias voltage that is used to bias the gate of the carrier amplifier transistor 328. The carrier input signal received at the carrier amplifier input node 322 is combined with the DC bias voltage output by the first inverter circuitry 324 at a combining node that is coupled to the gate terminal of the carrier amplifier transistor 328. In some embodiments, the carrier amplifier transistor 328 has a gate width of around 2 mm. The carrier amplifier transistor 328 outputs an amplified carrier signal. Lower frequency portions of the amplified carrier signal (e.g., the DC offset applied when the DC bias voltage and carrier input signal were combined) may be removed from the amplified carrier signal by the first RF coupling circuitry 334, while higher frequency (e.g., RF) portions of the amplified carrier signal are passed to the carrier amplifier output node 338.

The peaking input signal that is output at the second power divider output node 318 is received at a peaking amplifier input node 342 of the peaking amplifier 308. A first phase delay element 320 may be coupled between the second power divider output node 318 and a second input impedance matching network 341. The second input impedance matching network 341 may be coupled between the second power divider output node 318 and the peaking amplifier input node 342. The second phase delay element 320 may apply a phase shift of, for example, 90 degrees to the peaking input signal. The second input impedance matching network 341 may include a network of inductors, capacitors, and/or resistors configured to reduce an impedance mismatch between an input impedance of the peaking amplifier 308 and a source impedance (e.g., the impedance of a signal source coupled to the RF input node 312).

The peaking amplifier 308 may include, in addition to the peaking amplifier input node 342, a peaking amplifier transistor 348 (e.g., an embodiment of the amplifier transistor 102 of FIGS. 1, 2), a second reference transistor 346 (e.g., an example embodiment of the reference transistor 202 of FIG. 2), second inverter circuitry 344 (e.g., an example embodiment of the inverter circuitry 204 of FIG. 2), second decoupling circuitry 352 (e.g., an example embodiment of the decoupling circuitry 216 of FIG. 2), second RF coupling circuitry 354 (e.g., an example embodiment of the RF coupling circuitry 242 of FIG. 2), and a peaking amplifier output node 358.

Drain terminals of the peaking amplifier transistor 348 and the second reference transistor 346 may be coupled to a second drain voltage supply 350 (configured to supply a second drain voltage V_{DRAIN2} of, for example, around 48 V). The second decoupling circuitry 352 may be coupled between the peaking amplifier transistor 348 (e.g., a drain terminal thereof) and the reference transistor 346. In other embodiments, similar decoupling circuitry (e.g., decoupling circuitry 217 of FIG. 2) may be coupled to a source terminal of the reference transistor 326. The second decoupling circuitry 352 may reduce RF signal interference at the reference transistor 346.

The drain terminals of the peaking amplifier transistor 348 and the second reference transistor 346 may also be coupled to the peaking amplifier output node 358 via the second RF coupling circuitry 354. The gate terminal of the second reference transistor 346 and the source terminal of the peaking amplifier transistor 348 may each be coupled to a reference potential 336 (e.g., a ground voltage). The gate terminal of the peaking amplifier transistor 348 may be coupled to the peaking amplifier input node 342 and may be coupled to the source terminal of the second reference transistor 346 via the second inverter circuitry 344. The peaking amplifier transistor 348 and the second reference transistor 346 may be formed on the same substrate (semiconductor die). In some embodiments, the peaking amplifier transistor 348 and the second reference transistor 346 are formed on a substrate that is separate from the substrate on which the carrier amplifier transistor 328 and the first reference transistor 326 are formed. A threshold voltage of the second reference transistor 426 may be correlated with a threshold voltage of the peaking amplifier transistor 348, given changes in temperature, aging, or other applicable factors affecting the peaking amplifier 308. In this way, the DC bias voltage supplied at the gate terminal of the peaking amplifier transistor 348 (which is based on the source voltage at the source terminal of the second reference transistor 346) is dynamically adjusted to account for changes in the threshold voltage of the peaking amplifier transistor 348 due to temperature, aging, or other applicable factors. In some embodiments, the peaking amplifier transistor 348 has a gate width of around 5 mm.

The bias controller 310 may include a constant current source (e.g., an example embodiment of the constant current source 214 of FIG. 2) that is configured to supply a constant current (e.g., around 10 mA) at the source terminal of the second reference transistor 346. The constant current source of the bias controller 310 that provides the constant current to the source terminal of the second reference transistor 346 may be separate from the constant current source of the bias controller 310 that provides the constant current to the source terminal of the first reference transistor 326 in some embodiments. The bias controller 310 may include the second drain voltage supply 350 that supplies the second drain voltage V_{DRAIN2}. In some embodiments, the second drain voltage V_{DRAIN2} is greater than 40 V (e.g., around 48 V). During operation of the Doherty amplifier system 300, a source voltage at a source terminal of the second reference transistor 346 is inverted by the second inverter circuitry 344 to produce a DC bias voltage that is used to bias the gate of the peaking amplifier transistor 348. The peaking input signal received at the peaking amplifier input node 342 is combined with the DC bias voltage output by the second inverter circuitry 344 at a combining node that is coupled to the gate terminal of the peaking amplifier transistor 348. The peaking amplifier transistor 348 outputs an amplified peaking signal. Lower frequency portions of the amplified peaking signal (e.g., the DC offset applied when the DC bias voltage and peaking input signal were combined) may be removed from the amplified peaking signal by the second RF coupling circuitry 354, while higher frequency (e.g., RF) portions of the amplified peaking signal are passed to the peaking amplifier output node 358.

The carrier amplifier output node 338 and the peaking amplifier output node are each coupled to the combining node 340. The amplified carrier signal that is output at the carrier amplifier output node 338 is combined with the amplified peaking signal that is output at the peaking amplifier output node 358 to produce an amplified output signal. A first output impedance matching network 339 and a second phase delay element 360 may be coupled between the carrier amplifier output node 338 and the combining node 340. The first output impedance matching network 339 may include a network of inductors, capacitors, and/or resistors configured to reduce an impedance mismatch between an output impedance of the carrier amplifier 306 and the impedance of the load 366. The second phase delay element 360 may apply a phase shift of, for example, 90 degrees to the amplified carrier input signal.

A second output impedance matching network 359 may be coupled between the peaking amplifier output node 358 and the combining node 340. The second output impedance matching network 359 may include a network of inductors, capacitors, and/or resistors configured to reduce an impedance mismatch between an output impedance of the peaking amplifier 308 and the impedance of the load 366.

The combining node 340 is coupled to the RF output node 364. During operation of the Doherty amplifier system 300, the amplified output signal may be provided from the combining node 340 to the load 366 via the RF output node 364.

FIG. 4. shows an example graph 400 illustrating respective current flow (e.g., drain-source current) through each a reference transistor (e.g., the reference transistor 202, 326, 346, FIGS. 2, 3) and an amplifier transistor (e.g., the amplifier transistors 102, 328, 348, FIGS. 1-3) of an amplifier device (e.g., the amplifier device 100, 200, 300, FIGS. 1-3), across different gate voltages (e.g., the voltage differential between the gate terminals 106, 206, FIGS. 1, 2 and the source terminals 110, 210), in accordance with various embodiments. Current flow for various gate voltages for the reference transistor and the amplifier transistor are shown at different temperatures to illustrate how shifts in gate-source threshold voltage due to temperature are correlated between the reference transistor and the amplifier transistor. Curve 402 corresponds to the current through the reference transistor at around −40° C., curve 404 corresponds to the current through the amplifier transistor at around −40° C., curve 406 corresponds to the current through the reference transistor at around 25° C., curve 408 corresponds to the current through the amplifier transistor at around 25° C., curve 410 corresponds to the current through the reference transistor at around 90° C., curve 412 corresponds to the current through the amplifier transistor at around 90° C. In the present example, the transistors are considered to be “on” when the drain-source current is greater than or equal to around 1 mA for the reference transistor and around 100 mA for the amplifier transistor. The gate-source threshold voltage for each transistor, therefore, corresponds to the voltage at which the current through that transistor exceeds around 1 mA.

Thus, as shown by curves 402 and 404, the respective gate-source threshold voltages for the reference transistor and the amplifier transistor at a temperature of around −40° C. are each around 2.5 V. As shown by curves 406 and 408, the respective gate-source threshold voltages for the reference transistor and the amplifier transistor at a temperature of around 25° C. are each around 2.45 V. As shown by curves 410 and 412, the respective gate-source threshold voltages for the reference transistor and the amplifier transistor at a temperature of around 90° C. are each around 2.43 V. This illustrates that, even when the gate-source threshold voltages of the reference transistor and the amplifier transistor are shifted due to changes in temperature, the amounts by which the respective gate-source threshold voltages of these transistors shift are correlated with one another.

By using the reference transistor to provide the DC bias voltage to the gate terminal of the amplifier transistor, as described above, shifts in the gate-source threshold voltage of the amplifier transistor are inherently accommodated for (i.e., due to the correlation between the gate-source threshold voltages of the reference transistor and amplifier transistor given changes in temperature). It should be understood that changes in the gate-source threshold voltages of the reference transistor and the amplifier transistor are similarly correlated, given changes in device age and process variations.

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with) another element, and not necessarily mechanically. Thus, although the schematic shown in the figures depict one exemplary arrangement of elements, additional intervening elements, devices, features, or components may be present in an embodiment of the depicted subject matter.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

It should also be noted that at least some of the operations for the methods described herein may be implemented using software instructions stored on a computer useable storage medium for execution by a computer. As an example, an embodiment of a computer program product includes a computer useable storage medium to store a computer readable program. The computer-useable or computer-readable storage medium can be an electronic, magnetic, optical, electromagnetic, infrared, or semiconductor system (or apparatus or device). Examples of non-transitory computer-useable and computer-readable storage media include a semiconductor or solid-state memory, magnetic tape, a removable computer diskette, a random-access memory (RAM), a read-only memory (ROM), a rigid magnetic disk, and an optical disk. Current examples of optical disks include a compact disk with read only memory (CD-ROM), a compact disk with read/write (CD-R/W), and a digital video disk (DVD).

Alternatively, embodiments described herein may be implemented entirely in hardware or in an implementation containing both hardware and software elements. In embodiments which use software, the software may include but is not limited to firmware, resident software, microcode, etc.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. An amplifier device comprising:
a first transistor having a first gate terminal, a first source terminal, and a first drain terminal, wherein the first transistor is configured to amplify radio frequency (RF) signals received at the first gate terminal, and the first drain terminal is configured to be coupled to a voltage supply; and
a second transistor having a second gate terminal, a second source terminal, and a second drain terminal, wherein the second drain terminal is configured to be coupled to the voltage supply, and the second source terminal is coupled to the first gate terminal and is configured to receive a substantially constant current from a constant current source.

2. The amplifier device of claim 1, further comprising:
inverter circuitry coupled between the second source terminal of the second transistor and the first gate terminal of the first transistor, wherein the inverter circuitry is configured to:
invert a first voltage at the second source terminal of the second transistor to produce a second voltage; and
output the second voltage to the first gate terminal of the first transistor.

3. The amplifier device of claim 2, further comprising:
a bias tee coupled to the first gate terminal of the first transistor, wherein the bias tee is configured to combine the second voltage and the RF signals to apply a direct current (DC) voltage offset to the RF signals.

4. The amplifier device of claim 1, further comprising:
a semiconductor die on which the first transistor and the second transistor are formed.

5. The amplifier device of claim 4, wherein a first threshold voltage of the first transistor is correlated with a second threshold voltage of the second transistor, given variations in at least one of a temperature of the amplifier device or aging of the amplifier device.

6. The amplifier device of claim 1, wherein the voltage supply is configured to provide a voltage of greater than or equal to 40 V to the first drain terminal and the second drain terminal.

7. The amplifier device of claim 5, wherein the first transistor and the second transistor are each gallium nitride field effect transistors.

8. An amplifier system comprising:
an amplifier transistor having a first gate terminal, a first source terminal, and a first drain terminal;
bias circuitry comprising:
a reference transistor having a second gate terminal, a second source terminal, and a second drain terminal; and
inverter circuitry coupled between the second source terminal of the reference transistor and the first gate terminal of the amplifier transistor; and
a constant current source configured to supply a substantially constant current to the second source terminal of the reference transistor; and
a voltage supply coupled to the first drain terminal of the amplifier transistor and coupled to the second drain terminal of the reference transistor.

9. The amplifier system of claim 8, wherein the amplifier transistor and the reference transistor are formed on the same substrate.

10. The amplifier system of claim 8, further comprising:
a bias tee coupled between the bias circuitry and the first gate terminal of the amplifier transistor; and
a radio frequency (RF) signal source coupled to the first gate terminal of the amplifier transistor via the bias tee, wherein the RF signal source is configured to supply RF signals to the first gate terminal of the amplifier transistor and the bias circuitry is configured to provide a direct current (DC) bias voltage to the first gate terminal of the amplifier transistor.

11. The amplifier system of claim 10, wherein the inverter circuitry is configured to generate the DC bias voltage by inverting a source voltage at the second source terminal of the reference transistor.

12. The amplifier system of claim 8, wherein a first threshold voltage of the amplifier transistor is correlated with a second threshold voltage of the reference transistor, given variations in at least one of a temperature or aging.

13. The amplifier system of claim 8, wherein the voltage supply is configured to output a voltage of greater than or equal to 40 V to the first drain terminal of the amplifier transistor and the second drain terminal of the reference transistor.

14. An amplifier system comprising:
a carrier amplifier comprising:
a first amplifier transistor having a first gate terminal, a first source terminal, and a first drain terminal, wherein the first amplifier transistor is configured to amplify radio frequency (RF) signals received at the first gate terminal, and the first drain terminal is configured to be coupled to a first voltage supply; and
a first reference transistor having a second gate terminal, a second source terminal, and a second drain terminal, wherein the second drain terminal is configured to be coupled to the first voltage supply, and the second source terminal is coupled to the first gate terminal and is configured to receive a first constant current from a first constant current source; and
a peaking amplifier comprising:
a second amplifier transistor having a third gate terminal, a third source terminal, and a third drain terminal, wherein the second amplifier transistor is configured to amplify radio frequency (RF) signals received at the third gate terminal, and the third drain terminal is configured to be coupled to a second voltage supply; and
a second reference transistor having a fourth gate terminal, a fourth source terminal, and a fourth drain terminal, wherein the fourth drain terminal is configured to be coupled to the second voltage supply, and the fourth source terminal is coupled to the third gate terminal and is configured to receive a second constant current from a second constant current source.

15. The amplifier system of claim 14, further comprising:
first inverter circuitry coupled between the second source terminal of the first reference transistor and the first gate terminal of the first amplifier transistor; and
second inverter circuitry coupled between the fourth source terminal of the second reference transistor and the third gate terminal of the second amplifier transistor.

16. The amplifier system of claim 15, wherein the first inverter circuitry is configured to invert a first source voltage at the second source terminal of the first reference transistor to provide a first direct current (DC) bias voltage at the first gate terminal of the first amplifier transistor, and the second inverter circuitry is configured to invert a second source voltage at the fourth source terminal of the second reference transistor to provide a second DC bias voltage at the third gate terminal of the second amplifier transistor.

17. The amplifier system of claim 14, wherein the first amplifier transistor and the first reference transistor are formed on a first semiconductor die, and the second amplifier transistor and the second reference transistor are formed on a second semiconductor die.

18. The amplifier system of claim 17, wherein a first threshold voltage of the first amplifier transistor is correlated with a second threshold voltage of the first reference transistor, and a third threshold voltage of the second amplifier transistor is correlated with a fourth threshold voltage of the second reference transistor.

19. The amplifier system of claim 18, wherein the first voltage supply is configured to supply a first voltage of greater than or equal to 40 V to the first drain terminal of the first amplifier transistor and to the second drain terminal of the first reference transistor, and the second voltage supply is configured to supply a second voltage of greater than or equal to 40 V to the third drain terminal of the second amplifier transistor and to the fourth drain terminal of the second reference transistor.

20. The amplifier system of claim 15, wherein the first amplifier transistor, the second amplifier transistor, the first reference transistor, and the second reference transistor are gallium nitride field effect transistors.
